(19) United States
(12) Patent Application Publication
(10) Pub. No.: US 2019/0264881 A1
(43) Pub. Date: Aug. 29, 2019

(54) LED STRIP HOUSING APPARATUS

(71) Applicant: NINGBO HAIDER IMPORT AND EXPORT CO., LIMITED, Jiangbei (CN)

(72) Inventor: Mark SUTHERLAND, Calgary (CA)

(21) Appl. No.: 16/407,640

(22) Filed: May 9, 2019

Related U.S. Application Data
(63) Continuation-in-part of application No. 15/230,595, filed on Aug. 8, 2016.
(60) Provisional application No. 62/202,360, filed on Aug. 7, 2015.

(51) Int. Cl. F21S 4/20; H05B 33/08; H01L 33/50; H05B 37/02

(52) U.S. Cl. CPC F21S 4/20; H05B 37/0272; H01L 33/50; H05B 33/0857

(57) ABSTRACT

There is disclosed an LED lighting system for growing plants. In an embodiment, the system comprises an LED strip having a plurality of LEDs mounted thereon arranged in an array; and a control system for controlling the LEDs in response to an input to achieve a desired light spectrum. The LEDs mounted on the LED strip in array comprise LEDs emitting white light at one or more temperatures. The LEDs mounted on the LED strip in an array further comprise color LEDs emitting light at specific wavelengths, and are adapted to be individually controlled. The LED lighting system is adapted to receive feedback on the actual light spectrum emitted by the LEDs in order to achieve a desired light spectrum, and may be wirelessly controlled to adjust the lighting, as may be required.

### RELATED CASES

This application is a continuation-in-part of U.S. application Ser. No. 15/230,595, filed on Aug. 8, 2016, the contents of which are incorporated herein by reference.

### FIELD

The present disclosure relates to light emitting diode (LED) lighting systems.

### BACKGROUND

For certain specialized lighting applications such as greenhouse applications for growing plants, the lighting system is critical to achieving desired performance in terms of plant quality and yield. In prior art systems, high pressure sodium (“HPS”) lamps are often used in order to try to achieve better growth performance in plants, and while HPS lamps can be effective in achieving desired growth in plants due to a relatively high proportion of green and yellow light, it is estimated that plants can use only about 31% of the energy generated by HPS lamps, and a significant portion of the energy is simply lost as heat. If HPS lamps are placed closer to the plants try to improve performance, they can actually bleach the plants and damage them. Therefore, while effective for plant growth, HPS lamps are rather inefficient in terms of the amount of energy required to power them for desired plant growth performance.

What is therefore needed is an improved lighting system and apparatus which optimizes performance for selected plants, and addresses at least some of the limitations in the prior art.

### SUMMARY

The present disclosure relates to an LED lighting system and apparatus having an LED strip including a plurality of LEDs selected and arranged to achieve a broad spectrum of light for growth of cultivated plants.

In an aspect, there is provided an LED strip comprising a plurality of low wattage LEDs of different color, selected and arranged for optimal growth of cultivated plants by providing an even, broad spectrum light across a broad coverage area.

In an embodiment, the low wattage LEDs are selected and positioned on the LED strip to achieve a desired spectrums of light over a given area. The spectrum of light generated by the LEDs overlap to achieve a desired broad spectrum of light to achieve performance similar to HPS lamps at significantly improved efficiencies.

In another embodiment, the low wattage LEDs are powered at low wattages of about one watt per LED or less. Properly selected for their light spectrum, and positioned on an LED strip to achieve a broad spectrum of light, these low wattage LEDs are capable of producing a full spectrum of light with high efficiency.

In a preferred embodiment, the LEDs are powered at one watt, ½ watt, ¼ watt, or even ⅛ watt in order to achieve high energy efficiency, and to prolong their useful life by minimizing heat.

These low wattage LEDs powered at about 1 watt each or less may be positioned on LED strips that range from about 2-4 feet in length, with a relatively high concentration of low wattage LEDs per square foot of required lighting. For example, over a four foot length, an LED strip may have up to hundreds of LED chips powering individual LEDs covering different light spectrums.

In an embodiment, the plurality of low wattage LEDs are controlled by a control system which is adapted to control each of the low wattage LEDs individually, in order to generate a desired lighting condition over the entire length of the LED strip.

In an embodiment, the LEDs are individually controllable by the control system in order to generate a full-spectrum of light (approximately 400 nm-840 nm).

In another embodiment, the LED colors comprise red, green and blue lights selected and arranged on the LED strip at predetermined intervals.

In another embodiment, the LED colors comprise red, white and blue lights selected and arranged on the LED strip at predetermined intervals.

In another embodiment, the LEDs are controlled by a computer in order to determine a change in the spectrum of light over a selected period of time.

In another embodiment, the system includes one or more sensors for sending the growth of plants under the lighting system. This feedback allows the control system to adjust the LEDs, either collectively or individually, in order to achieve a desired growth of the plants over a predetermined period of time.

In an aspect, the LED strips holding the LEDs are adapted to be received in an LED strip apparatus, including retaining flanges which allow an LED strip carrier to be slidably inserted or removed from one end of the LED strip apparatus. Different LED strips containing different arrangement of LEDs may be used for optimal growth of different types of plants.

In this respect, before explaining at least one embodiment of the system and method of the present disclosure in detail, it is to be understood that the present system and method is not limited in its application to the details of construction and to the arrangements of the components set forth in the following description or illustrated in the drawings. The present system and method is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

FIG. 1A shows an illustrative perspective view of an LED strip housing in accordance with an illustrative embodiment.

FIG. 1B shows an illustrative detailed view of the LED strip housing of FIG. 1A.

FIG. 2 shows a detailed cross-sectional view of the LED strip housing of FIGS. 1A and 1B, including an LED strip carrier receiving channel in accordance with an illustrative embodiment.

FIGS. 3A and 3B show perspective views of end caps in accordance with an illustrative embodiment.

FIG. 4A shows a perspective view of an LED strip carrier in accordance with an illustrative embodiment.

FIG. 4B shows a detailed perspective view of the LED strip carrier of FIG. 4A.

FIG. 4C shows a detailed cross-sectional view of the LED strip carrier of FIGS. 4A and 4B.

FIG. 5A shows an illustrative perspective view of an LED strip housing in accordance with another illustrative embodiment.

FIG. 5B shows a detailed cross-sectional view of the LED strip housing of FIG. 5A.

FIG. 6, shows an illustrative example of an LED strip having a plurality of LEDs of different color, selected and arranged for optimal growth of cultivated plants.

FIG. 7 shows an illustrative example of a control system for controlling the LEDs to achieve a desired light spectrum over a period of time.

FIG. 8 shows an illustrative example of a generic computer device which may embody a control system for controlling the LEDs.

FIG. 9 shows an illustrative example of a mini greenhouse with a transparent cover for receiving an LED lamp thereon.

FIG. 10 shows an illustrative example of an LED lamp lighting the mini greenhouse of FIG. 9.

FIG. 11 shows a close-up view of the LED lamp mounted on top of the mini greenhouse cover.

FIG. 12 shows a close-up view of the underside of the LED lamp mounted on top of the mini greenhouse cover.

FIG. 13 shows a schematic diagram of an LED strip with an illustrative arrangement of LEDs having different light wavelengths for producing a composite light.

FIG. 14 shows a schematic diagram of an LED strip with another illustrative arrangement of LEDs having different light wavelengths for producing a composite light.

FIG. 15 shows an illustrative color spectrum resulting from the arrangement of LEDs shown in FIG. 13.

FIG. 16 shows an illustrative color spectrum resulting from the arrangement of LEDs shown in FIG. 14.

FIG. 17 shows an illustrative color spectrum resulting from an adjustment of LEDs either individually or in groups.

### DETAILED DESCRIPTION

As noted above, the present disclosure relates to to light emitting diode (LED) lighting systems, and more particularly to low wattage LEDs selected and arranged to produce a desired light spectrum for growing plants which is energy efficient.

The LED strip may comprise a plurality of low wattage LEDs of different color, selected and arranged for optimal growth of cultivated plants by providing an even, broad spectrum light across a broad coverage area.

In an embodiment, the low wattage LEDs are selected and positioned on the LED strip to achieve a desired spectrums of light over a given area. The spectrum of light generated by the LEDs overlap to achieve a desired broad spectrum of light to achieve performance similar to HPS lamps at significantly improved efficiencies.

In another embodiment, the low wattage LEDs are powered at low wattages of about one watt per LED or less. Properly selected for their light spectrum, and positioned on an LED strip to achieve a broad spectrum of light, these low wattage LEDs are capable of producing a full spectrum of light with high efficiency.

In a preferred embodiment, the LEDs are powered at one watt, ½ watt, ¼ watt, or even ⅛ watt in order to achieve high energy efficiency, and to prolong their useful life by minimizing heat.

These low wattage LEDs powered at about 1 watt each or less may be positioned on LED strips that range from about 2-4 feet in length, with a relatively high concentration of low wattage LEDs per square foot of required lighting. For example, over a four foot length, an LED strip may have up to hundreds of LED chips powering individual LEDs covering different light spectrums.

In an embodiment, the plurality of low wattage LEDs are controlled by a control system which is adapted to control each of the low wattage LEDs individually, in order to generate a desired lighting condition over the entire length of the LED strip.

In an embodiment, the LEDs are individually controllable by the control system in order to generate a full-spectrum of light (approximately 400 nm-840 nm).

In another embodiment, the LED colors comprise red, green and blue lights selected and arranged on the LED strip at predetermined intervals.

In another embodiment, the LED colors comprise red, white and blue lights selected and arranged on the LED strip at predetermined intervals.

In another embodiment, the LEDs are controlled by a computer in order to determine a change in the spectrum of light over a selected period of time.

In another embodiment, the system includes one or more sensors for sending the growth of plants under the lighting system. This feedback allows the control system to adjust the LEDs, either collectively or individually, in order to achieve a desired growth of the plants over a predetermined period of time.

In an aspect, the LED strips holding the LEDs are adapted to be received in an LED strip apparatus, including retaining flanges which allow an LED strip carrier to be slidably inserted or removed from one end of the LED strip apparatus. Different LED strips containing different arrangement of LEDs may be used for optimal growth of different types of plants.

The LED strip carrier receiving channel of the LED strip housing apparatus includes retaining flanges which allow an LED strip carrier to be slidably inserted or removed from one end of the LED strip apparatus while the other end of the strip apparatus remains covered with an end cap.

In another aspect, the LED strip carrier receiving channel of the LED strip housing apparatus is accessible from one end of the apparatus with one end cap removed, while an outer cover remains installed in position over the length of the LED strip carrier receiving channel.

In another aspect, the end caps are adapted to include plug-in connectors which allow an electrical connection to the LEDs on the LED strip carrier simply by installing the end caps in position.

In another aspect, the LED strip carrier is readily exchangeable with another LED strip carrier of the same size, but having LEDs with different luminosity or colors mounted thereon, suitable for a different lighting environments or applications.

An illustrative embodiment will now be described in more detail with reference to the drawings.

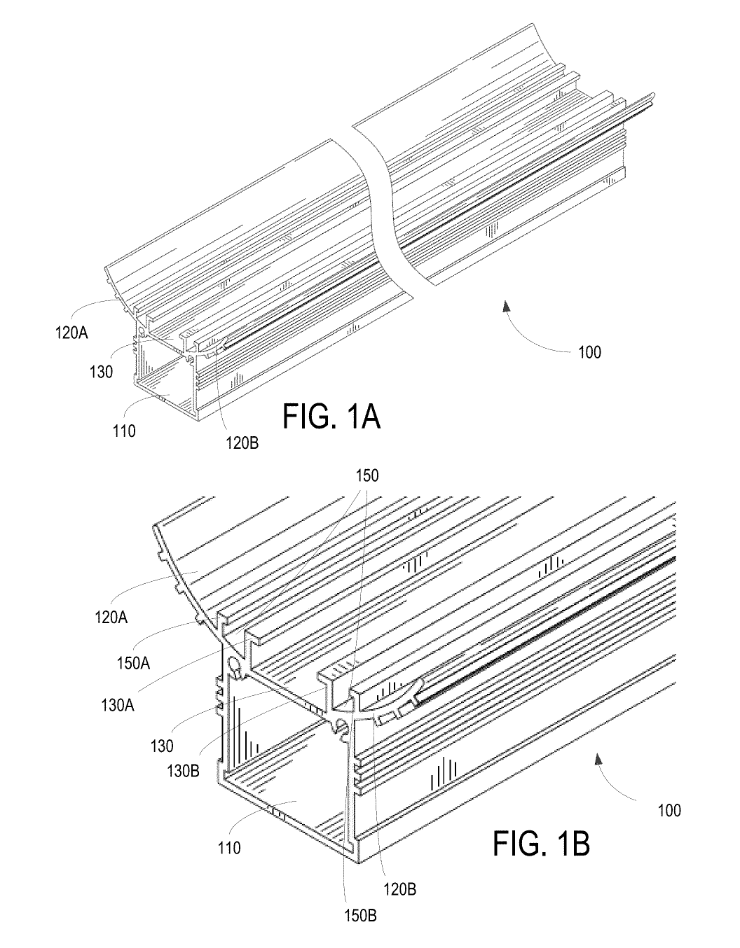

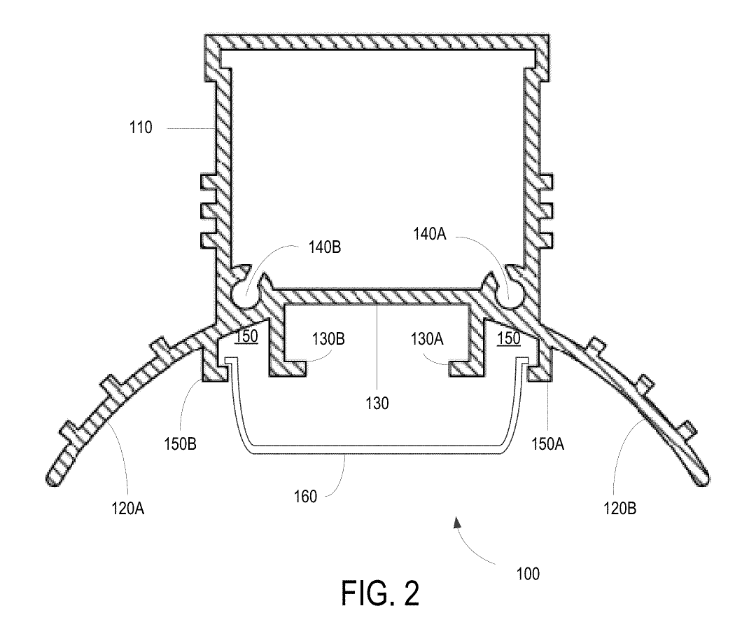

Referring to FIG. 1A, shown is an illustrative perspective view of an LED strip housing 100 in accordance with an illustrative embodiment. In this example, the LED strip housing 100 includes a generally elongate tube 110, with wings 120A, 120B extending from either side of the generally elongate tube 110. In this illustrative example, the generally elongate tube 110 is generally rectangular, and the wings 120A, 120B are curved and generally aligned with one side of the generally elongate rectangular tube 110. The inside of the generally elongate rectangular tube 110 provides space for electric wiring, circuit boards and electronics (not shown) required to power the LEDs. In use, the LED strip housing 100 is oriented such that the curved wings 120A, 120B are at the bottom of the apparatus (see FIG. 2), acting to direct light generally downwardly over an area to be illuminated.

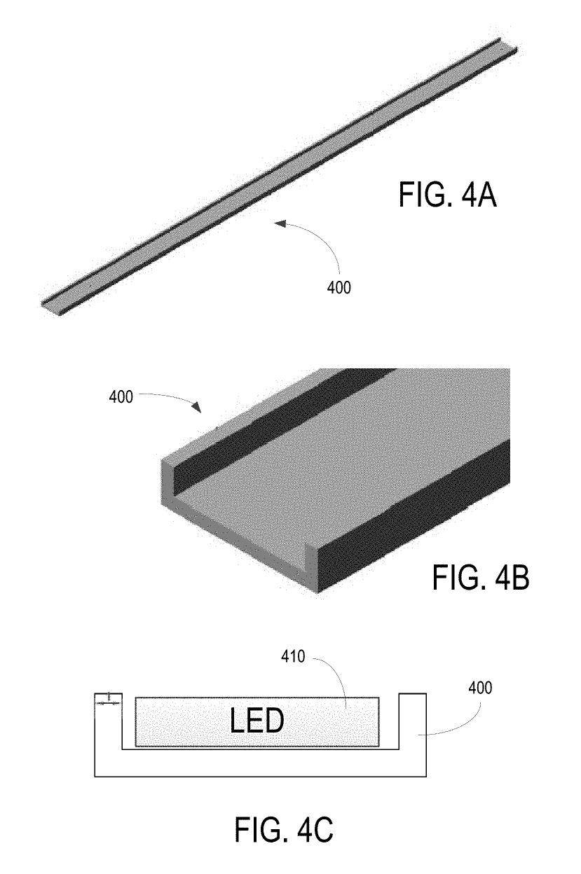

Still referring to FIG. 1A, and referencing the detailed view in FIG. 1B, the LED strip housing 110 further includes an LED strip carrier receiving channel 130 adapted to slidably receive an LED strip carrier 400 (see FIG. 4A) therein. In this example, the LED strip carrier receiving channel 130 includes retaining flanges 130A, 130B adapted to retain an LED strip carrier 400 in position with lateral extensions directed inwardly towards the carrier receiving channel 130, even with the LED strip housing 100 oriented for use with the LED strip carrier receiving channel 130 located at the bottom of the LED strip housing (as in FIG. 2).

An outer cover receiving channel 150 adapted to slidably receive an outer cover 160 (see FIG. 2) which covers and protects the LED strip carrier 400 received within the LED strip carrier receiving channel 130.

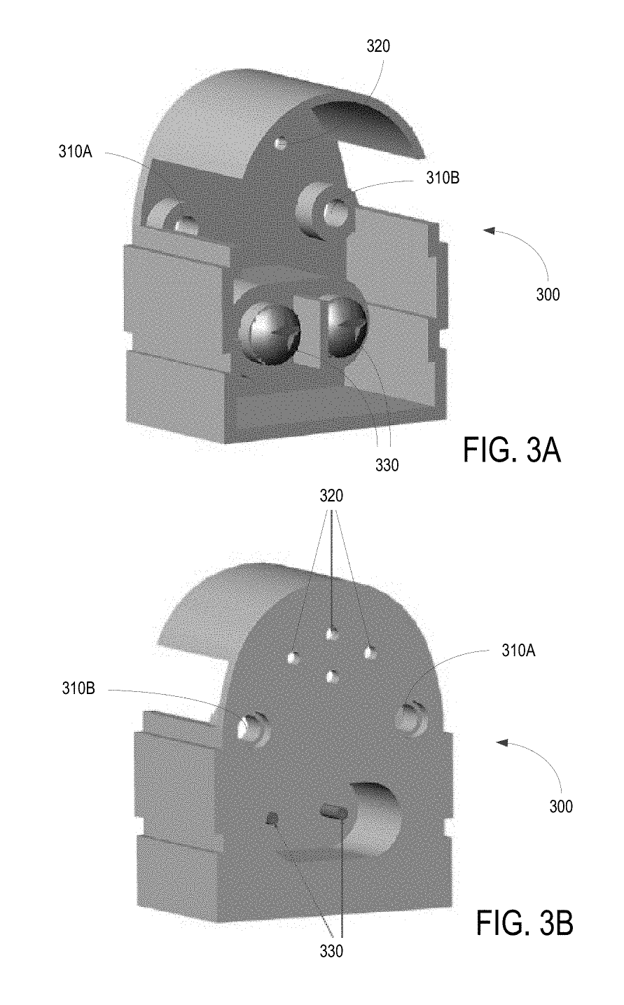

Now referring to FIG. 2, shown is a cross-sectional view of the LED strip housing 100 of FIGS. 1A and 1B, including a more detailed view of the LED strip carrier receiving channel 130, and the outer cover receiving channel 150 in accordance with an illustrative embodiment. In this detailed view, the profile of the LED strip housing 100 is shown including a generally rectangular tube 110 which provides space for electric wiring, circuit boards and electronics as described previously. At the bottom corners of the rectangular tube 100, generally circular shaped channels are adapted to receive fasteners, such as screws, which retain end caps 300 (see FIGS. 3A and 3B, for example) in place on either end of the LED strip housing 100.

Still referring to FIG. 2, the LED strip carrier receiving channel 130 is sized and positioned between the outer cover receiving channel 150 such that an LED strip carrier 400 (see FIGS. 4A-4C) can be slidably inserted or removed from one end, even as a transparent or translucent outer cover 160 remains installed in position in the outer cover receiving channel 150, covering the length of the LED strip carrier receiving channel 130. Consequently, the LED strip carrier 400 can readily be replaced by removing just one end cap 300 on one end of the LED strip housing 100.

Now referring to FIGS. 3A and 3B, shown are perspective views of end caps 300 in accordance with an illustrative embodiment. FIG. 3A shows a front perspective view, and FIG. 3B shows a corresponding rear perspective view. As shown, the end caps 300 include apertures 310A, 310B which are adapted to align with the generally circular shaped channels 140A, 140B (see FIG. 2) in the rectangular tube 110 to fasten end caps 300 on either end. Vent holes 320 may be provided to allow the minimal heat generated from the LEDs to escape through the end caps 300.

Still referring to FIGS. 3A and 3B, plug-in connectors 330 as shown are adapted to connect the LED strip to wiring, circuit boards and electronics within the rectangular tube (not shown). Contact points on the other side of the end caps 300 allow for electrical wire connections to a power source, such as household mains electricity for example, via a power cable.

Now referring to FIG. 4A, shown is a perspective view of an LED strip carrier 400 in accordance with an illustrative embodiment. In an embodiment, the LED strip carrier 400 is adapted to mount an LED strip thereon by fastening LEDs 410 to the strip. LEDs 410 may be fastened to the LED strip carrier 400 by means of an adhesive, such as fluorescent glue. It will be appreciated, however, that other adhesive means may be used to affix the LED strip in position in the LED strip carrier 400.

FIG. 4B shows a detailed perspective view of the LED strip carrier 400 of FIG. 4A, which is shaped as a channel in this illustrative embodiment. FIG. 4C shows a detailed cross-sectional view of the LED strip carrier 400. In an embodiment, the LED strip carrier 400 is shaped as a bracket, such that the length of the LED strip carrier remains relatively rigid. This allows the LED strip carrier 400 to retain its shape as an LED strip is mounted to it. Furthermore, the relative rigidity of the LED strip carrier 400 allows it to be slidably inserted and removed from the LED strip carrier receiving channel 130 within the LED strip housing 100, as described earlier.

The LED strip carrier 400 is adaptable to mount various types of LED strips having different luminosity and colors, suitable for different lighting environments and lighting applications.

Advantageously, the LED strip carrier 400 can be readily inserted and removed from one end of the LED strip housing 100 by simply removing one end cap 300, allowing efficient replacement of LED strips. This will save a significant amount of time, particularly in larger installation sites such as office buildings.

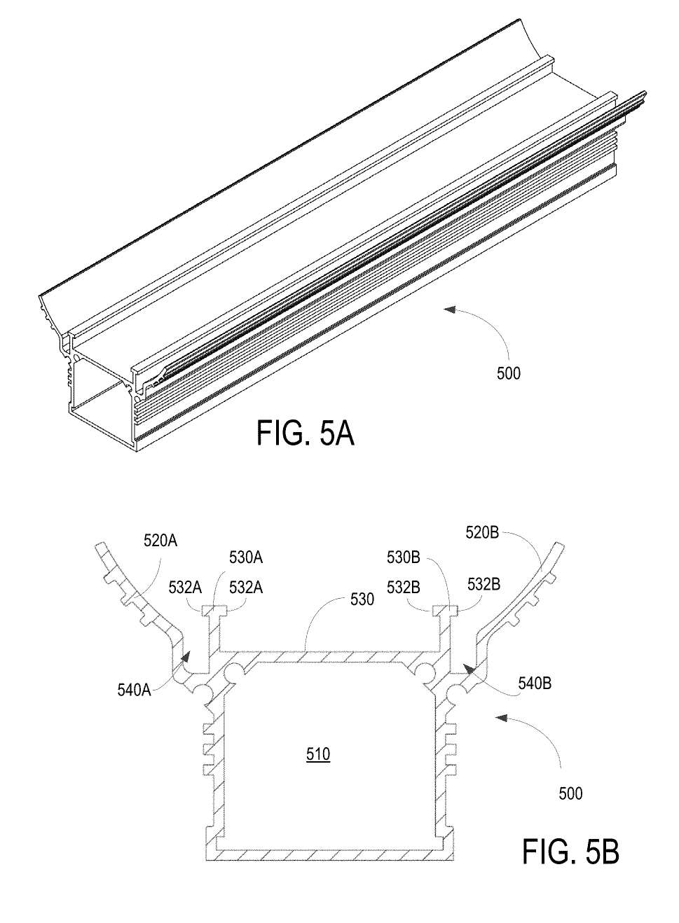

Now referring to FIGS. 5A and 5B, shown is an illustrative perspective view of an LED strip housing 500 in accordance with another illustrative embodiment. As detailed in FIG. 5B, the cross-sectional view of the LED strip housing of FIG. 5A again shows a generally elongate tube 510 with wings 520A, 520B. In this embodiment, the wings 520A, 520B are attached to the sides of the tube 510, and form channels 540A, 504B.

Still referring to FIG. 5B, the LED strip housing 500 further includes LED strip carrier receiving channel 530 having retaining flanges 530A, 530B with dual-sided lateral extensions 532A, 532B. The inner lateral extensions retain an LED strip carrier 400 slidably received within the LED strip carrier receiving channel 530 from either side of the LED strip housing 500. The outer lateral extensions may receive a cover (not shown) which may be positioned over the LED strip carrier 400 and LEDs 410 mounted thereon.

Advantageously, the LED strip housing 500 is adapted to allow LEDs to be quickly installed or replaced by removing one end cap 300 on one side to access the housing 500 and slidably insert or remove an LED strip carrier 400 into or out of the LED strip carrier receiving channel 530, without the need to remove any cover mounted over the LED lighting.

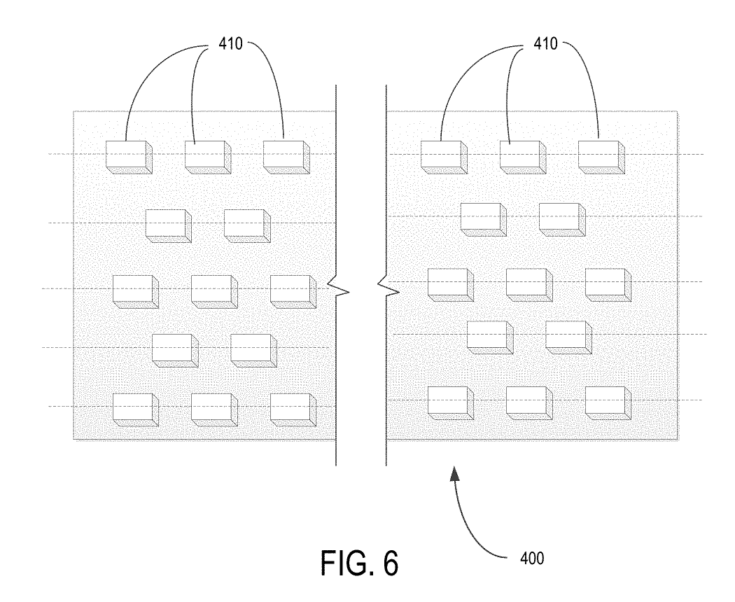

Now referring to FIG. 6, shown is an illustrative example of an LED strip having a plurality of LEDs 410 of different color, selected and arranged in a pattern on an LED strip carrier 400. In an embodiment, the LEDs 410 are selected to have different colors comprising red, green and blue LEDs. The spectrum of light generated by the different colored LEDs overlap to achieve an even, broad spectrum of light across a broad coverage area.

In another embodiment, the LEDs may also include “white” light at different temperatures, such as “soft white” “soft white” at around 2700K-3000K, “bright white” at 3500K-4100K, or “daylight” at around 5000K-6500K

In another embodiment, the low wattage LEDs are powered at low wattages of about one watt per LED or less. Properly selected for their light spectrum, and positioned on the LED strip 4100 to achieve a broad spectrum of light, these low wattage LEDs are capable of producing a full spectrum of light with high efficiency.

In a preferred embodiment, the LEDs are powered at one watt, ½ watt, ¼ watt, or ⅛ watt in order to achieve higher energy efficiency, and to prolong their useful life by minimizing energy lost as heat.

As an illustrative example, these low wattage LEDs powered at about 1 watt each or less may be positioned on LED strips that range from about 1-4 feet in length, with a relatively high number of low wattage LEDs 410 per square foot of required lighting. For example, over a four foot length, an LED strip may have up to hundreds of low wattage LED chips powering individual LEDs covering different light spectrums. Each of these LED chips are adapted to be controlled individually, or as a group, by a lighting control system.

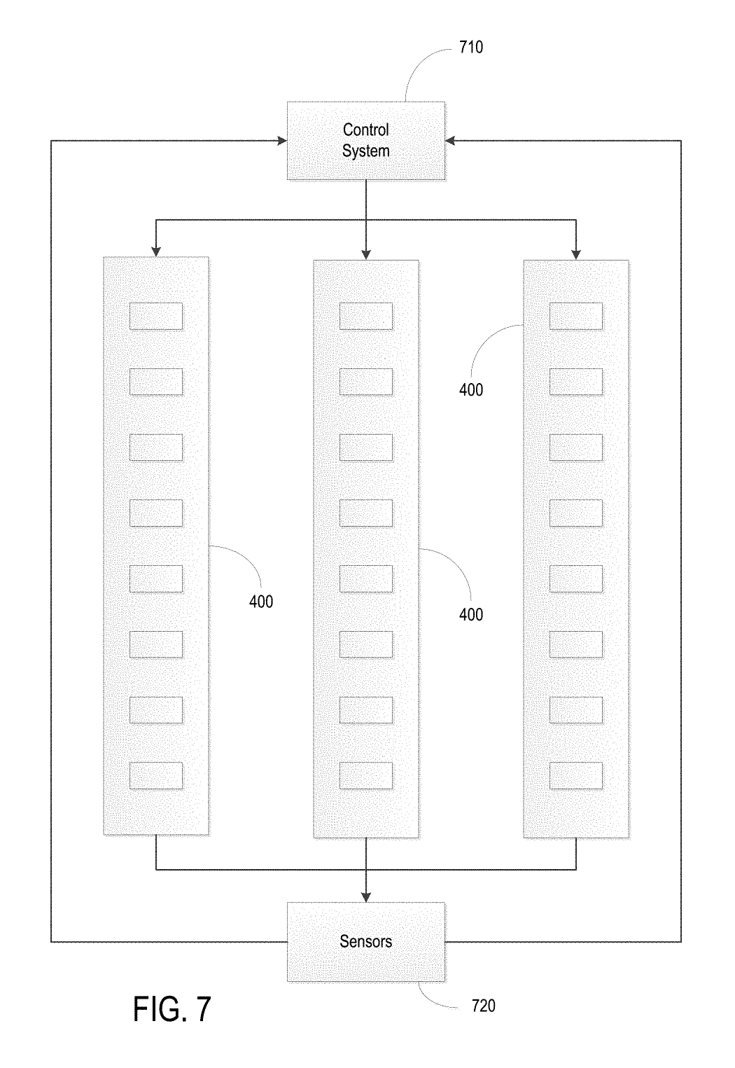

FIG. 7 shows an illustrative example of a control system 710 for controlling the LEDs 410 to achieve a desired light spectrum, which may vary over a period of time. By way of example, certain plant varieties may require different lighting conditions when the plants initially start to germinate, in comparison to when the plants are rapidly growing, or when they are near maturity and ready to be harvested.

In a preferred embodiment, one or more sensors 720 are used to provide feedback to the lighting control system. These sensors may include, for example, still or video cameras, temperature sensors, humidity sensors, CO₂ sensors, and light spectrum sensitive optical sensors in light meters to measure the light spectrum actually being produced over lighting area. These optical sensors may be positioned at regular intervals to ensure that an even light is achieved everywhere in the lighted area.

In an embodiment, a Wi-Fi module 730 may be provided to allow remote control of the control system 710 via a remotely connected computing device, such as embodied in a smartphone, tablet, laptop, or other computer device. This Wi-Fi module enables a user to remotely program the LEDs 410 on the LED strip carrier 400.

In an embodiment, the LEDs on the LED strip carrier 400 may be wired to allow control of the LEDs individually, or by group. For example, the LEDs may be wired together by color or type to allow a user to dim or brighten a particular wavelength, or dim or brighten a type of light, such as a soft white light at 2700K, or a daylight LED at 5500K.

In another embodiment, the control system may be programmed with different growth modules for different types and varieties of plants being grown. By identifying and selecting a customized growth module for a given type of plant, the control system is able to vary the lighting conditions over the life of a crop of plants, and to verify that a desired growth pattern is being achieved by comparing the growth to its database. The control system is also able to vary lighting conditions over a 24 hour cycle, such that the lighting is optimal for a given type or variety of plant.

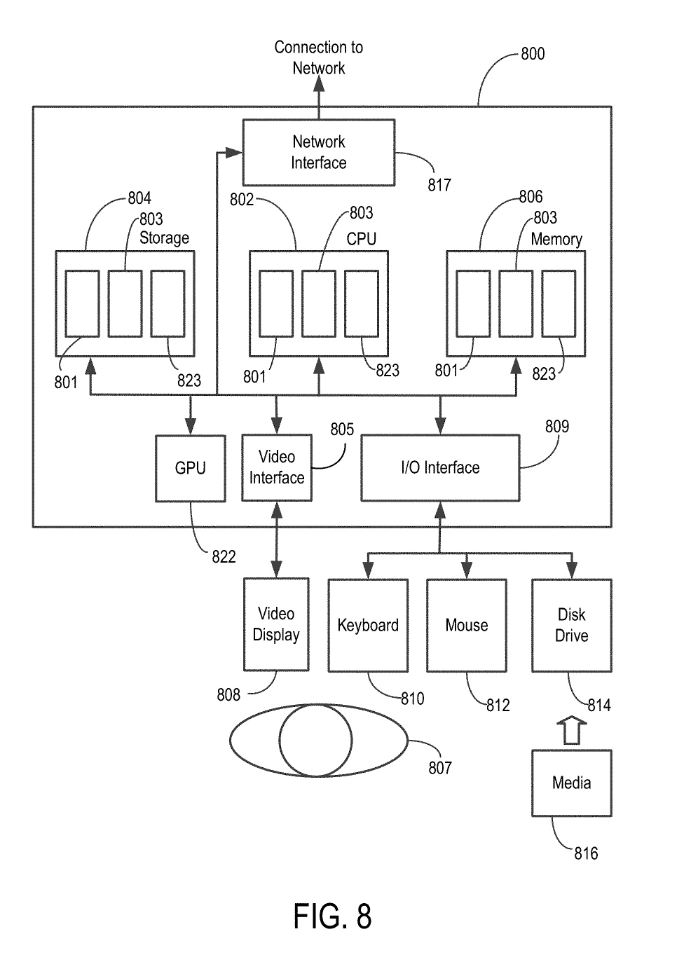

FIG. 8 shows an illustrative example of a generic computer device which may embody a control system for controlling the LEDs. As shown, generic computer device 800 may include a central processing unit (“CPU”) 802 connected to a storage unit 804 and to a random access memory 806. The CPU 802 may process an operating system 801, application program 803, and data 823. The operating system 801, application program 803, and data 823 may be stored in storage unit 804 and loaded into memory 806, as may be required. Computer device 800 may further include a graphics processing unit (GPU) 822 which is operatively connected to CPU 802 and to memory 806 to offload intensive image processing calculations from CPU 802 and run these calculations in parallel with CPU 802. An operator 810 may interact with the computer device 800 using a video display 808 connected by a video interface 805, and various input/output devices such as a keyboard 810, pointer 812, and storage 814 connected by an I/O interface 809. In known manner, the pointer 812 may be configured to control movement of a cursor or pointer icon in the video display 808, and to operate various graphical user interface (GUI) controls appearing in the video display 808. The computer device 800 may form part of a network via a network interface 811, allowing the computer device 800 to communicate with other suitably configured data processing systems or circuits. A non-transitory medium 816 may be used to store executable code embodying one or more embodiments of the present method on the generic computing device 800.

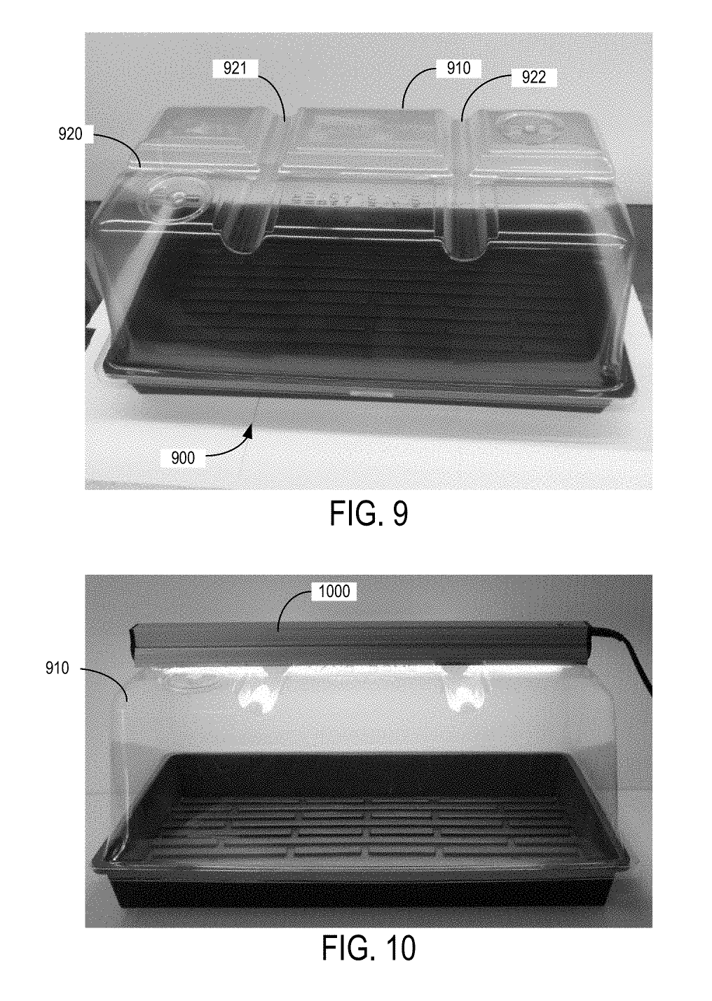

FIG. 9 shows an illustrative example of a mini greenhouse 900 with a transparent cover 910 for receiving an LED lamp 1000 thereon. The transparent cover includes channels or slots 920, 921, 922 shaped and sized to receive an LED strip housing 500 thereon.

FIG. 10 shows an illustrative example of an LED lamp 1000 lighting the mini greenhouse 900 of FIG. 9 with a spectrum of light. As will be explained in further detail below, this spectrum of light is produced by a combination of different types of LEDs, including “white” LEDs and colored LEDs.

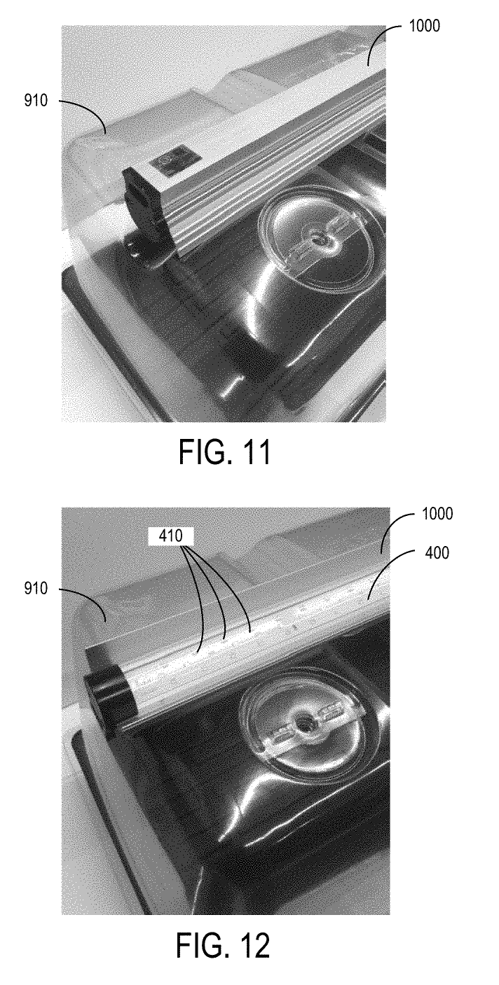

FIG. 11 shows a close-up view of the LED lamp 1000 mounted on top of the mini greenhouse cover 910. As shown, the end of the LED lamp 1000 has an end cap 300 to cover an LED strip carrier 400 and electrically connect the LEDs 410 on the LED strip carrier 400 to additional wiring in the LED strip housing 500, and to a power source to power the LEDs 410.

FIG. 12 shows a close-up view of the underside of the LED lamp 100, with the LED strip carrier 400 and LEDs 410 shown mounted to the LED strip carrier 400 in an array. Illustrative examples of this array will now be described.

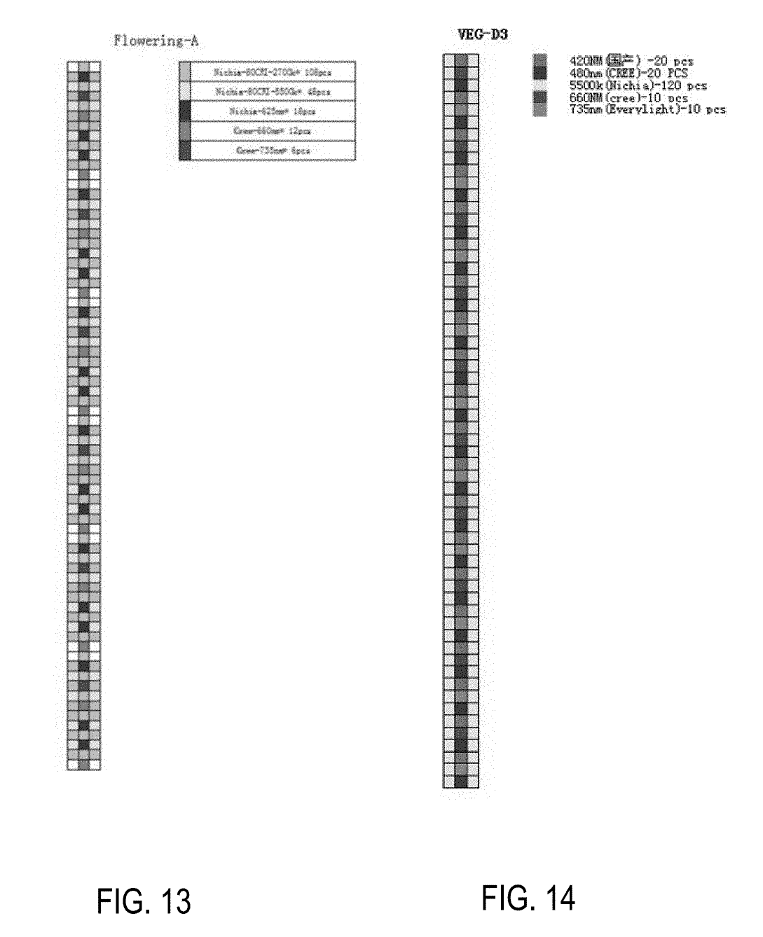

FIG. 13 shows a schematic diagram of an LED strip carrier 400 with an illustrative array of LEDs 410 mounted thereon and having different light wavelengths for producing a composite light spectrum. In an illustrative embodiment, some of the LEDs may produce “white” light at different color temperatures. In this illustrative example, a “soft white” LED at 2700K and a “daylight” LED at 5500K is used as part of the array. Other LEDs mounted to the LED strip carrier 400 may be colored LEDs producing specific wavelengths that have been selected to supplement the white light to produce a desired color spectrum. In this illustrative example, the colored LEDs are at 625 nm, 660 nm, and 735 nm. These colored wavelengths may be specifically selected to be beneficial for growing certain types of plants, and their intensity may be controlled such that the color spectrum may be varied by controlling all of the LEDs together.

Still referring to FIG. 13, in an embodiment, the intensity of the colored LEDs is determined by their arrangement and their number in the array. Alternatively, as described earlier, the colored LEDs may also be wired together as a group, such that they can be controlled as a group.

For example, in an embodiment, the LED colors comprise red, green and blue lights selected and arranged on the LED strip at predetermined intervals.

In another embodiment, the LED colors comprise red, white and blue lights selected and arranged on the LED strip at predetermined intervals.

In an embodiment, the positioning of the red and blue lights many be in the middle row, while the white LEDs are positioned on the outside rows to create a better balance of lights. This positioning may also help with hiding the blue and red lights in the middle row, which may be visually annoying to operators monitoring the plants.

As will be appreciated, arranging the LEDs may produce a light spectrum that may be beneficial for particular uses. By way of example, the control system may be programmed to optimize lighting conditions for growing certain types of plants.

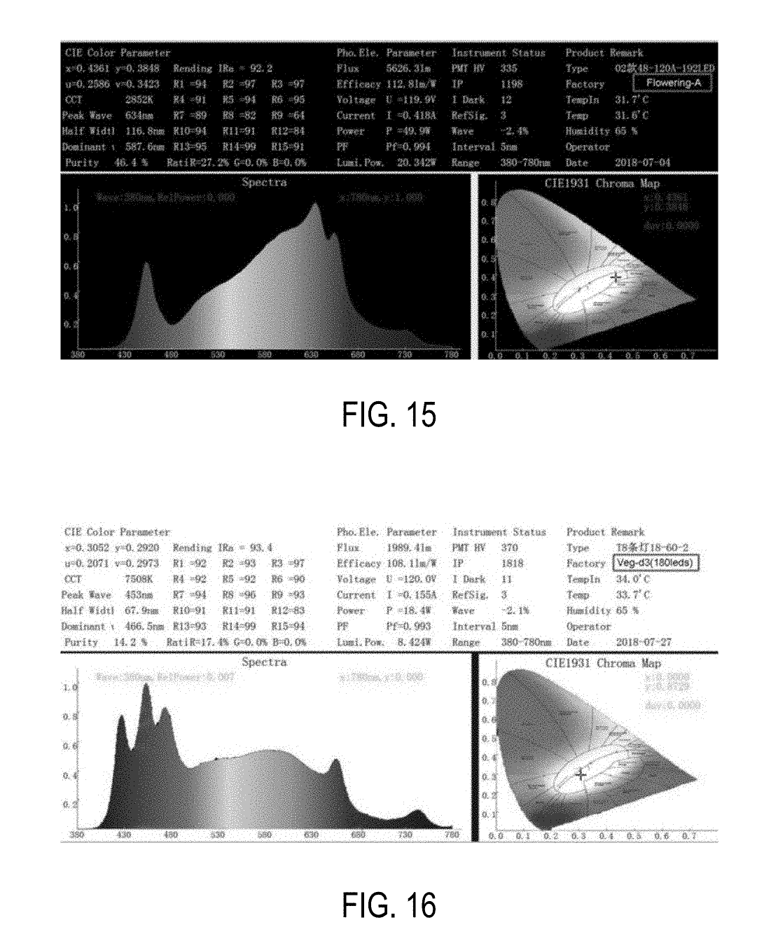

FIG. 14 shows a schematic diagram of an LED strip with another illustrative arrangement of LEDs having different light wavelengths for producing a composite light. As shown, the LED array includes outer rows of “daylight” at approximately 5500K, combined with an alternating arrangement of color LEDs at 420 nm, 480 nm, 660 nm and 735 nm. These colored LEDs may be specifically selected to be beneficial for growing certain types of vegetables, for example, and the resulting light spectrum is shown in FIG. 16.

As will be appreciated, by mounting the LEDs 410 on a LED strip carrier 400 that can be easily removed and replaced with another, the present system and apparatus allows the LED lamp to be adapted to many different uses.

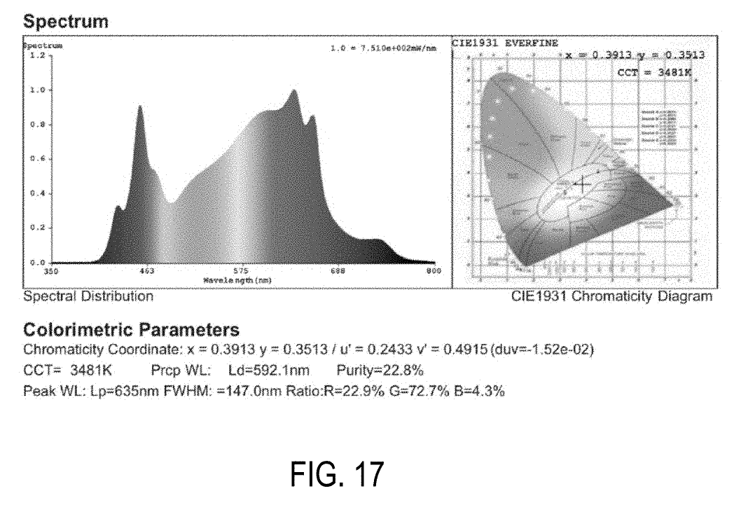

FIG. 17 shows an illustrative color spectrum resulting from an adjustment of LEDs either individually or in groups. It will therefore be understood that an arrangement of LEDs can be controlled, for example by turning individual LEDs or a group of LEDs on or off, or varying the intensity of individual LEDs or groups of LEDs, to achieve a desired color spectrum for a given application.

In an embodiment, the control system is programmable and adapted to adjust the light spectrum over time. For example, the control system may be programmed to dim or turn off the lights for a period of time, or to vary the light spectrum over a prescheduled growth cycle for a plant.

In an embodiment, the control system is adapted to receive feedback on the actual light spectrum emitted by the LEDs in order to achieve a desired light spectrum. That is to say, the control system may utilize a sensor to provide a feedback loop, and adjust any LEDs as may be necessary to achieve a desired light spectrum if there is any discrepancy. For example, the control system may have in its memory a desired light spectrum for a particular plant variety. In order to achieve optimal lighting for the plant, the control system may run a pre-determined lighting program for the length of a given growth cycle.

In an embodiment, the control system is adapted to provide an alert communication via a wireless module to a remote computing device in the event of an error condition. The error condition may be, for example, an electrical or mechanical failure.

The error condition could also be a failure to achieve a desired light spectrum due to an incorrectly installed array of LEDs, requiring an operator to change the LED strip carrier to run a lighting program.

In another embodiment, the error condition may be an interruption in operation of the lighting system, whether interruption of a power source, or some other interruption by a user.

In an embodiment, the LED strip carrier receiving channel is adapted to slidably receive and retain an LED strip carrier utilizing retaining flanges having extensions directed inwardly towards the LED strip carrier receiving channel.

In another embodiment, the LED strip carrier receiving channel is generally rectangular with an open side, and adapted to receive and retain an LED strip carrier shaped as a bracket.

In another embodiment, the LED strip housing apparatus further comprises an outer cover receiving channel for receiving a transparent or translucent outer cover which covers and protects the LED strip carrier received within the LED strip carrier receiving channel.

In another embodiment, the outer cover receiving channel is positioned adjacent to and outside of the LED strip carrier receiving channel, leaving the LED strip carrier receiving channel accessible from either end even with an outer cover installed in position.

In another embodiment, the LED strip housing apparatus of claim 5, further comprises end caps mountable to either end of the housing, the end caps adapted to connect the LED strip to wiring, circuit boards and electronics within the rectangular tube.

In another embodiment, the LED strip carrier receiving channel is accessible with an outer cover installed in position by removing one of the end caps.

In another embodiment, the LED strip housing apparatus further comprises wings extending from either side of the generally elongate tube, the wings positioned to direct light towards a direction.

In another embodiment, the wings are curved to form a generally concave shape.

In another embodiment, the apparatus comprises an integral one piece body.

In another embodiment, the LED strip carrier receiving channel is formed between retaining flanges that are a part of the integral one piece body.

In another embodiment, the retaining flanges include lateral extensions extending inwardly to retain the LED strip carrier within the LED strip carrier receiving channel.

In another embodiment, the retaining flanges further include lateral extensions extending outwardly to retain an outer cover installed over the LED strip carrier receiving channel.

In another embodiment, the integral one piece body of the apparatus further includes generally circular shaped channels for receiving fasteners.

Thus, in an aspect, there is provided an LED lighting system for growing plants, comprising: an LED strip having a plurality of LEDs mounted thereon arranged in an array; and a control system for controlling the LEDs to achieve a desired light spectrum.

In an embodiment, the LEDs mounted on the LED strip in array comprise LEDs emitting white light at one or more temperatures.

In another embodiment, the LEDs mounted on the LED strip in an array further comprise color LEDs emitting light at specific wavelengths.

In another embodiment, the LEDs mounted on the LED strip in an array are adapted to be individually controlled.

In another embodiment, the LEDs mounted on the LED strip in an array are adapted to be controlled in like groups.

In another embodiment, the LEDs mounted on the LED strip are arranged in rows.

In another embodiment, the LEDs are adapted to be controlled by the control system by row.

In another embodiment, the system further comprises a wireless module for remotely communicating with the control system via a computing device.

In another embodiment, the wireless module is a Wi-Fi connection module.

In another embodiment, the LED lighting system further comprises one or more sensors adapted to detect the light spectrum emitted by the plurality of LEDs, and to provide feedback to the control system in order to provide confirmation whether the desired spectrum of light is being achieved.

In another embodiment, the sensor is an optical sensor in a light meter.

In another embodiment, the control system is programmable and adapted to adjust the light spectrum over time.

In another embodiment, the control system is adapted to receive feedback on the actual light spectrum emitted by the LEDs in order to achieve a desired light spectrum.

In another embodiment, the control system is adapted to compare the light spectrum emitted by the LEDs with a desired light spectrum for a particular plant, and to adjust the LEDs to achieve the desired light spectrum if there is a discrepancy.

In another embodiment, the control system is adapted to provide communication via a wireless module to a remote computing device in the event of an error condition.

In another embodiment, the error condition is an electrical or mechanical failure.

In another embodiment, the error condition is a failure to achieve a desired light spectrum due to an incorrectly installed array of LEDs.

In another embodiment, the error condition is an interruption in operation of the lighting system.

While illustrative embodiments of the invention have been described above, it will be appreciate that various changes and modifications may be made without departing from the scope of the present invention.

1. An LED lighting system for growing plants, comprising:
an LED strip having a plurality of LEDs mounted thereon arranged in an array; and
a control system for controlling the LEDs in response to an input to achieve a desired light spectrum.

2. The LED lighting system of claim 1, wherein the LEDs mounted on the LED strip in array comprise LEDs emitting white light at one or more temperatures.

3. The LED lighting system of claim 3, wherein the LEDs mounted on the LED strip in an array further comprise color LEDs emitting light at specific wavelengths.

4. The LED lighting system of claim 1, wherein the LEDs mounted on the LED strip in an array are adapted to be individually controlled.

5. The LED lighting system of claim 1, wherein the LEDs mounted on the LED strip in an array are adapted to be controlled in like groups.

6. The LED lighting system of claim 1, wherein the LEDs mounted on the LED strip are arranged in rows.

7. The LED lighting system of claim 5, wherein the LEDs are adapted to be controlled by the control system by row.

8. The LED lighting system of claim 1, wherein the system further comprises a wireless module for remotely communicating with the control system via a computing device.

9. The LED lighting system of claim 8, wherein the wireless module is a Wi-Fi connection module.

10. The LED lighting system of claim 1, further comprising one or more sensors adapted to detect the light spectrum emitted by the plurality of LEDs, and to provide feedback to the control system in order to provide confirmation whether the desired spectrum of light is being achieved.

11. The LED lighting system of claim 10, wherein the sensor is an optical sensor in a light meter.

12. The LED lighting system of claim 10, wherein the control system is programmable and adapted to adjust the light spectrum over time.

13. The LED lighting system of claim 12, wherein the control system is adapted to receive feedback on the actual light spectrum emitted by the LEDs in order to achieve a desired light spectrum.

14. The LED lighting system of claim 13, wherein the control system is adapted to compare the light spectrum emitted by the LEDs with a desired light spectrum for a particular plant, and to adjust the LEDs to achieve the desired light spectrum if there is a discrepancy.

15. The LED lighting system of claim 14, wherein the control system is adapted to provide communication via a wireless module to a remote computing device in the event of an error condition.

16. The LED lighting system of claim 15, wherein the error condition is an electrical or mechanical failure.

17. The LED lighting system of claim 15, wherein the error condition is a failure to achieve a desired light spectrum due to an incorrectly installed array of LEDs.

18. The LED lighting system of claim 15, wherein the error condition is an interruption in operation of the lighting system.
